(19) United States
(12) Patent Application Publication
(10) Pub. No.: US 2010/0084261 A1
(43) Pub. Date: Apr. 8, 2010

(54) METHOD FOR FABRICATING POLYMERIC WAVELENGTH FILTER

(75) Inventors: Kun-Yi Lee, Taipei (TW); Wei-Ching Chuang, Taipei (TW); Yen-Juei Lin, Taipei (TW); Cheng-Che Lee, Taipei (TW); Wei-Yu Lee, Taipei (TW)

Correspondence Address: WPAT, PC;INTELLECTUAL PROPERTY ATTORNEYS, 2030 MAIN STREET, SUITE 1300, IRVINE, CA, 92614, US

(73) Assignee: China Institute of Technology, Taipei City (TW)

(21) Appl. No.: 12/246,508

(22) Filed: Oct. 7, 2008

(51) Int. Cl. C23C 14/00

(52) U.S. Cl. 204/192.26

(57) ABSTRACT

The present invention discloses a method for fabricating polymeric wavelength filter, which method for forming gratings patterns on the UV polymer involves three processing steps. First, a gratings pattern is holographically exposed using a two-beam interference pattern on a positive photo-resister film. A 20-nm-thick nickel thin film is then sputtered onto the positive photo-resister film to form a nickel mold. This nickel mold on the photo-resister film then can be subsequently used to transfer the final gratings pattern onto a UV cure epoxy polymer. Whereby, a polymer film can be spun coated on the cure epoxy substrate so as to simplify the fabrication process for obtaining a polymer wavelength filter with good aspect ratio of gratings pattern.

### FIELD OF THE INVENTION

The present invention relates to a method for fabricating polymeric wavelength filter, especially to a technique that uses the micro-molding process to simplify the fabrication process for obtaining a polymer wavelength filter with good aspect ratio of gratings pattern.

### BACKGROUND OF THE INVENTION

Gratings are used in integrated optics for several purpose, including wavelength filtering, sensing, optical measuring technique, spectral narrowing of laser output, optical power coupling in waveguide systems, etc. In particular, surface grating with high diffraction efficient can be utilized in many applications, such as holographic image storage, liquid crystal anchoring, optical filters, or resonant couplers. In surface grating applications, the grating depths significantly affect the performance of optical devices. If grating-assisted waveguides are used in optical filter applications, shallow grating, which will result in small coupling coefficients, will lead to an unfeasibly narrow transmission bandwidth and will therefore require a long coupling length to attain a specific transmission. Furthermore, when optical light sources with a short wavelength are used in optical components, the higher-order peaks of propagation modes cannot be eliminated from the filter; this will result in low efficiency of the first-order peak of propagation modes if the aspect ratio between the depth and the period of gratings is low. A deep waveguide Bragg grating is of interest in practical application such as semiconductor waveguides or input-output coupler in integrated-optics. Recently, L. Zhu et al. demonstrated polymeric multi-channel band pass filters [Reference: L. Zhu, Y. Huang, W. Green, A. Yariv, “Polymeric multi-channel bandpass filters in phased-shifted Bragg waveguide gratings by direct electron beam writing” Optics Express, Vol. 12, Issue 25, 2004, pp. 6372-6376] and optical add-drop multiplexers [Reference: L. Zhu, Y. Huang, A. Yariv, “Integration of a multimode interference coupler with a corrugated sidewall Bragg grating in planar polymer waveguide,” IEEE Photon. Techn. Lett., vol. 18, no. 6, 2006, pp. 740-742] with corrugated sidewall Bragg grating using deep grating. Their results showed that the grating length can be shortened to around 500 μm.

The conventional method for fabricating grating involves patterning and etching. Typical techniques used for patterning gratings on polymer waveguides include soft lithography, proximate-contact lithography on a silicon-nitride grating, and nanoimprint technique. Kocabas et al reported the fabrication of a grating on OG 146 polymer using soft lithography, e-beam direct writing, and stamp transfer techniques. Then, a BCB polymeric ridge waveguide was fabricated on the grating using reaction ion etching technique. The grating fabrication process is similar to our previous work except for the e-beam writing technique [Reference: W. C. Chuang, C. T. Ho, and W. C. Wang, “Fabrication of a high resolution periodical structure using a replication process” Opt. Express 13 (2005),6685-6692]. In proximate-contact lithography and nanoimprint technique, the gratings were fabricated on silicon-nitride or quartz stamps by the RIE technique. The aspect ratio of the gratings can be controlled by varying the etching rate of the RIE.

Kim et al fabricated Bragg grating using the nanoimprint technique to successfully transfer the gratings pattern onto a polymer layer [Reference: D. Kim, W. Chin, S. lee, S. Ahn, and K. Lee, Appl. Phys. Lett. 88 (2006), 071120-1-071120-3]. The nanoimprint process is cost effective and simple method for fabricating a stamp. However, it has certain drawbacks, as explicitly mentioned in Ref. 15. These drawbacks may restrict the use of this method in fabricating a Bragg grating filter. In these techniques, the RIE process transfers a gratings pattern from the top polymer layer to the core underneath and it increases the difficulty of obtaining accurate and smooth waveguide gratings. For soft lithography, S. Schmid et al. used a rigid PDMS, “h-PDMS”, to fabricated periodic structure with feature size below 100 nm and aspect ratio (as their definition depth/width of pattern) 1.25 [Reference: H. Schmid and B. Michel, “Siloxane pilymers for high-resolution, high-accuracy soft lithography,” Macromolecules 2000, 33, 3042-3049]. T. Lee et al. also demonstrated high aspect ratio periodic structures using h-PDMS and show good stamp transfer fidelity when compared with general PDMS. In their experiment, the aspect ratio reached 4.2 with periodic below 1500 nm [Reference: Tae-Woo Lee, Oleg Mitrofanov, and Julia W. P. Hsu, “Pattern-transfer fidelity in soft lithography: the role of pattern density and aspect ratio,” Adv. Func. Mat., 2005, 15, 1683-1688]. However, the main drawbacks of h-PDMS are the brittle nature of h-PDMS and the thermal curing requirements of such material. Because the relatively low toughness of the h-PDMS made relief features with these geometries susceptible to fracture, elements of h-PDMS tended to fail due to fracture of the relief features during fabrication of the elements or during their use, particularly in molding applications. In this invention, gratings patterns on the photo-resister are prepared by the holographic interferometric technique. This technique offers important advantages compared to other techniques in that it can easily control the period and depth of gratings, and it is more naturally suited to the production of high-resolution gratings than other techniques, yielding good uniformity of the grating period with greater ease. In addition, the theoretical limit of the frequency of the interference pattern produced by two intersecting beams is half the wavelength of the incident beam. Thus, the grating period is limited only by the wavelength of the light source.

The materials used as well as the fabrication processes are important factors in manufacturing optical elements for different applications. Sol-gel hybrid (SGH) materials can be easily used for the fabrication of grating diffraction by the holographic interferometric technique; however such material cannot be used for the fabrication of gratings pattern with high aspect ratios, and since they are brittle material, they find applications. In our previous paper [Reference: W. C. Chuang, C. T. Ho, and W. C. Wang, “Fabrication of a high resolution periodical structure using a replication process” Opt. Express 13 (2005),6685-6692.], our polymer diffraction gratings were fabricated using the holographic interferometric technique with a photo-resister (Ultra 123) to obtain a gratings pattern with a high aspect ratio. Then, the patterned photo-resister was used as a master mold to transfer the pattern onto a polydimethylsiloxane (PDMS, rubber) thin film, which was cast against the patterned resist. However, it was observed that when the depth of the grating was larger than 350 nm, which is accompanied by a grating period smaller than 500 nm, some of the gratings appeared to affix to the bottom and to each other after release from the photo-resister mold. These structures appeared as though the grating period had been broadened. This sticking effect is also observed, when the aspect ratio between the depth and the period is greater than 0.7. This sticking effect increased with the aspect ratio because the fins are less rigid. Therefore, in this paper we present a technique wherein the holographic interferometric and micro-molding process to create a grating structure with a high aspect ratio on a polymer waveguide.

### SUMMARY OF THE INVENTION

The technique of forming gratings patterns on the UV polymer simply involves three processing steps. First, a gratings pattern is holographically exposed using a two-beam interference pattern on a positive photo-resister film. A 20-nm-thick nickel thin film is then sputtered onto the positive photo-resister mold to obtain a nickel mold. This nickel mold on the photo-resister is subsequently used to transfer the final gratings pattern onto a UV cure epoxy polymer, and then obtain a polymer wavelength filter with good aspect ratio of gratings pattern.

### BRIEF DESCRIPTION OF THE DRAWINGS

FIG. 1 shows a basic grating fabrication process in accordance with the present invention;

FIG. 2 shows an embodiment of grating fabrication process in accordance with the present invention;

FIG. 3 shows the AFM picture and measurement result for the grating on photo-resister with 532 nm grating period and 418 nm grating depth;

FIG. 4 shows the SEM micrographs of gratings on UV polymer with 532 nm grating period and 418 nm grating depth;

FIG. 5 shows the AFM micrographs of gratings on UV polymer (532 nm grating period and 418 nm grating depth);

FIG. 6 shows the SEM micrograph of the channel waveguide filter;

FIG. 7 shows the SEM micrograph of the cross-section of the channel waveguide;

FIG. 8 shows the mode field pattern of the channel waveguide device in accordance with the present invention;

FIG. 9 shows the transmission spectrum of the polymeric wavelength filter with 0.5 cm-long grating length in accordance with the present invention; and

FIG. 10 shows the transmission spectrum of the polymeric wavelength filter with 0.8 mm-long grating length in accordance with the present invention (sample 1: 1.6 μm thick guiding layer, sample 2: 2.02 μm thick guiding layer).

### DETAILED DESCRIPTION OF THE PREFERRED EMBODIMENT

### I. The Concept of the Present Invention

The present invention of forming gratings patterns on the UV polymer involves three processing steps. First, a gratings pattern is holographically exposed using a two-beam interference pattern on a positive photo-resister film. A 20-nm-thick nickel thin film is then sputtered onto the positive photo-resister film to obtain a nickel mold having grating pattern. This nickel mold on the photo-resister film then can be subsequently used to transfer the final gratings pattern onto a UV polymer (UV cure epoxy polymer). The following sections describe the process involved in grating fabrication.

### II. The Basic Fabrication Process of the Present Invention

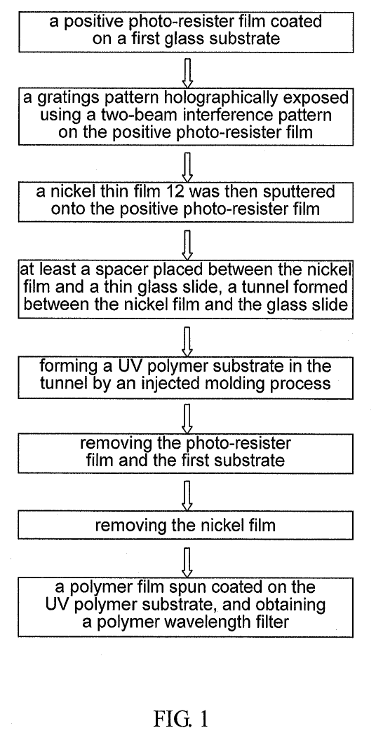

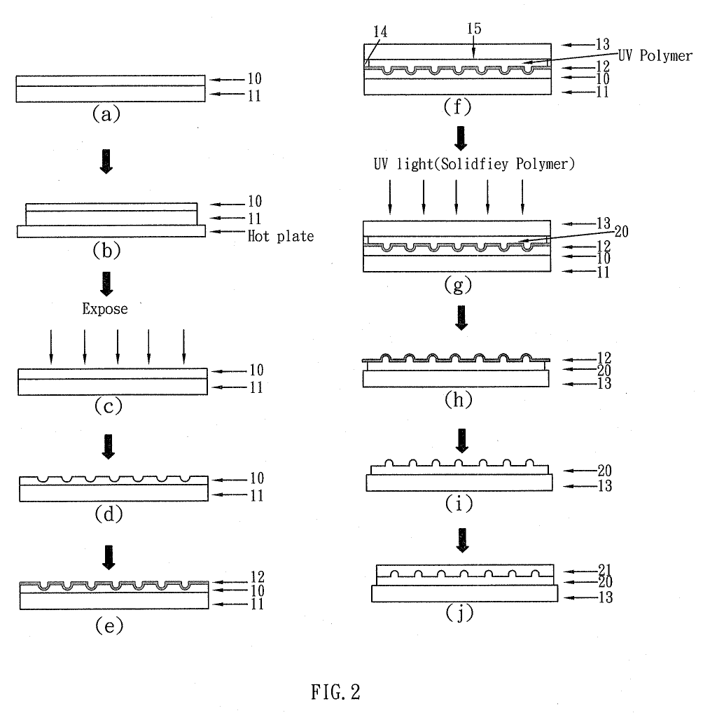

Referring to FIGS. 1 and 2, the basic method for fabricating the polymer wavelength filter comprises following steps:

(A) a positive photo-resister film 10 coated on a first glass substrate 11;

(B) a gratings pattern holographically exposed using a two-beam interference pattern on the positive photo-resister film 10;

(C) a nickel thin film 12 was then sputtered onto the positive photo-resister film 10;

(D) at least a spacer placed between the nickel film 12 and a thin glass slide 13, a tunnel 15 formed between the nickel film 12 and the glass slide 13;

(E) forming a UV polymer substrate 20 (a cure epoxy substrate) in the tunnel 15 by an injected molding process;

(F) removing the photo-resister film 10 and the first substrate 11;

(G) removing the nickel film 12; and

(H) a polymer film 21 spun coated on the UV polymer substrate 20, and obtaining a polymer wavelength filter.

### III. The Embodiment of Grating Fabrication Process of the Present Invention

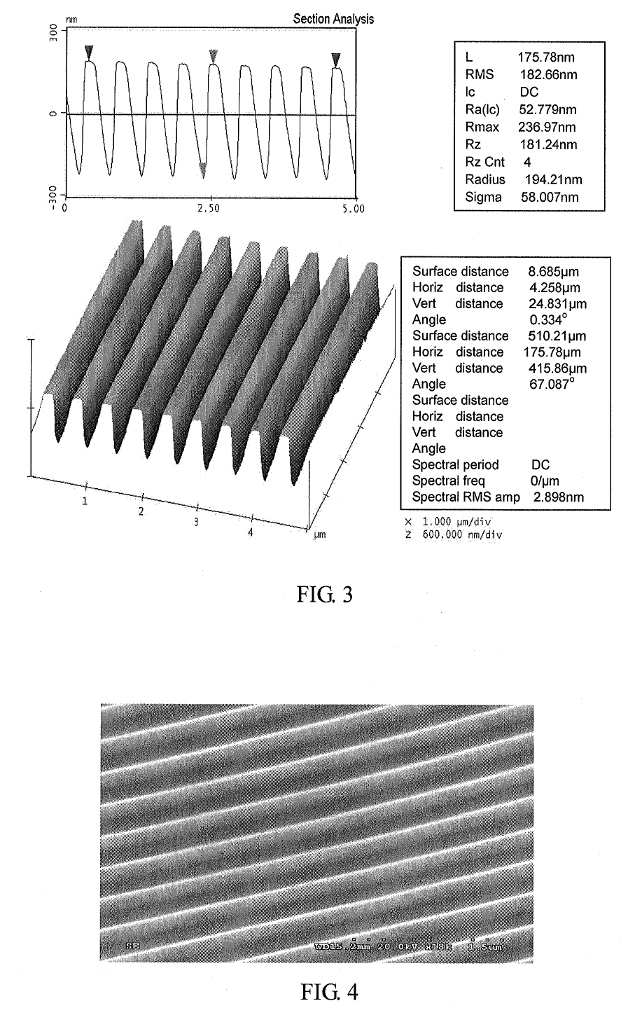

The master gratings patterns on a positive photo-resister (Ultra123, Microchem. Corp. Mass.) were holographically exposed using a two-beam interferometer technique (Referring to FIG. 2(a)-(d)). The details of this process have been described in our previous reports. Based on our results, we found that the grating period and the corresponding depth of the gratings pattern can be accurately controlled down to an error rate of less than 1%. We also found that a high aspect ratio of almost 1:1 between the depth and the period of the grating structure could be obtained using this process. The profiles of the grating were measured by using an atomic force microscope (AFM). FIG. 3 showed the AFM result of the photo-resister with a grating period and grating depth of 530 nm and 416 nm. The surface roughness of the grating is around 2 nm.

Since the adhesion between the photo-resister (Ultra 123) and the other polymers is strong, the polymers cannot be easily separated from Ultra 123. On the other hand, the Ni metal is easily to be etched away from any polymers by the FeCl₃ etching solution. A nickel thin film was then sputtered onto the positive photo-resister film by an RF sputtering system for about 1 min (FIG. 2(e)) to form a nickel mold. The power source is 50 W, and the work pressure is restricted to less than 5×10⁻³ Torr. The thickness of nickel is approximately 20 nm. The profiles of the nickel molds were measured using an atomic force microscope (AFM). A table comparing the grating geometry on the metal and photo-resister molds shows that the overall dimension was reduced when gratings patterns were transferred from the photo-resister to the nickel mold (Table 1). These results indicated an average reduction of 0.41% or 2.7 nm in the periods. On the other hand, the average reduction in depths was reduced by as much as 13.7% and 14-36 nm.

The final gratings pattern was transferred onto three types of cure epoxy substrate 20 having different shrinkage ratio using an injected molding process from the positive photo-resister film 10 that was sputtered on nickel film 12 (FIG. 2(f)-(i)). The solidified reaction of polymers often results in volume contraction because water or other solvent byproduct is released out after reaction. However, in the case of the OG 146 polymer, almost no water or solvent byproduct is released out after reaction. The fabrication procedure is described as follows. A spacer with thickness 400 μm was placed between the nickel mold and a thin Pyrex glass slide 13 to form a tunnel 15. The mold was supported by another Pyrex glass slide 13 to create a support for the positive photo-resister film 10. After injecting the procure UV polymers (OG146, Epoxy Technology Inc., AT9575, AT8105, NTT Inc.) into the tunnel 15 between the nickel film 12 and the glass slide 13 by using a fine tip syringe, the liquid solution automatically spread and filled up the space between the nickel film 12 and glass slide 13. A UV curing lamp with a wavelength range of 300-400 nm was used to crosslink the UV polymer at an intensity of 100 mW/cm² for 1 to 2 min. After the UV polymer was fully cured, the sample was immersed in an acetone solution to remove the positive photo-resister. The sample was then immersed in a FeCl₃ solution (FeCl₃: H₂O=1:1; solution' temperature was maintained at 25° C.) to remove the nickel film, and the final gratings pattern are formed on the UV polymer 20.

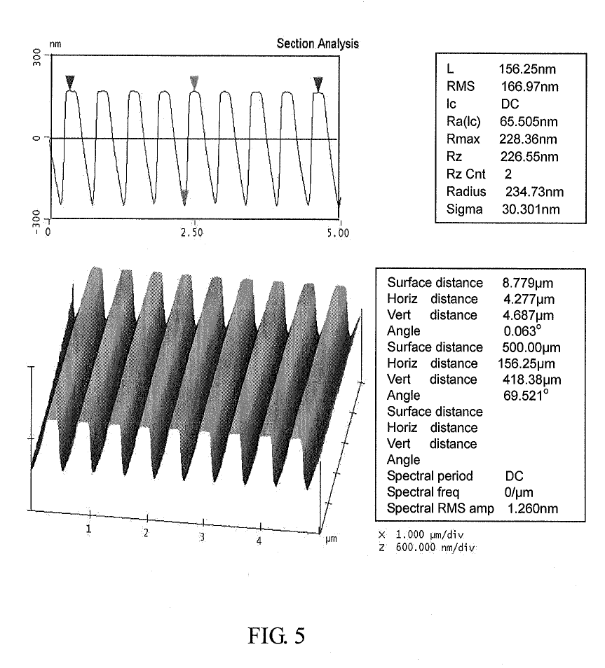

The AFM and SEM measurements of the gratings on a UV polymer are listed in Table 1. Referring to FIGS. 4 and 5, the AFM and SEM micrographs of the gratings on a UV polymer show OG146 polymer gratings with a 532 nm period and 418 nm depth, indicating that a periodical structure with a high aspect ratio can be obtained by using the above-mentioned fabrication process. We can conclude that when the shrinkage ratio of the polymer is large, the reduction in the grating dimension appears to be higher (Referring to Table 1). For example, when the shrinkage ratio of the polymer is 6%, the grating period and depth can be reduced by as much as 2.2% and 25.3% respectively, when gratings pattern are transferred from the positive photo-resister to UV polymer. Overall, for OG146 polymer, the depth reduced by an average of around 8.2% from the original positive photo-resister mold, and the period was transferred much better when an average reduction of 1.6% occurred when gratings pattern transforming the positive photo-resister to UV polymer. For the grating on the OG146 polymer, which has a modulation depth of 418 nm, a transmission diffraction efficiency of 32% was obtained. The efficiency was measured at a wavelength of 325 nm, and it was calculated by dividing the intensity of the first diffracted order by the intensity of the incident probe beam.

TABLE 1
Results of gratings from the SEM and AFM measurement
on photo-resister (PR), Ni, and UV polymers.

| Master grating | | | | Polymer | | | |
|---|---|---|---|---|---|---|---|
| mold | | Master mold | | grating | | Ultra123 to | |
| (Ultra123) | | with Ni | | (UV) | | polymer error | |
| Period | Depth | Period | Depth | Period | Depth | Period | Depth |
| (nm) | (nm) | (nm) | (nm) | (nm) | (nm) | (nm) | (nm) |
| 508 | 192 | 506 | 173 | (1)505 | 172 | 3(0.6%) | 20(10.4%) |
| 508 | 274 | 506 | 253 | (1)501 | 253 | 7(1.4%) | 21(7.7%) |
| 508 | 393 | 503 | 371 | (1)494 | 366 | 14(2.8%) | 27(6.8%) |
| 508 | 263 | 506 | 227 | (2)501 | 208 | 7(1.4%) | 54(21%) |
| 508 | 363 | 505 | 347 | (2)501 | 301 | 7(1.4%) | 62(17%) |
| 505 | 372 | 503 | 348 | (2)491 | 296 | 14(2.8%) | 76(20%) |
| 514 | 162 | 511 | 146 | (3)514 | 125 | 10(1.9%) | 37(23%) |
| 514 | 276 | 510 | 255 | (3)514 | 206 | 11(2.1%) | 70(25.3%) |
| 514 | 377 | 512 | 350 | (3)513 | 283 | 11(2.1%) | 94(25.1%) |

* (1)OG146 with a shrinkage ratio 0%, (2)AT9575 with a shrinkage ratio 4%, (3)AT8105 with a shrinkage ratio 6%.

### IV. Application of the Present Invention for the Fabrication of the Polymeric Waveguide Bragg Filter

In order to investigate polymeric wavelength filters, we used a SU8 polymer (Micro Chem SU8-2005) as a core layer; this has a low optical loss (<0.4 dB/cm) and has a refractive index between 1.56 and 1.57 at a wavelength of 1.55 μm. For the fabrication of the polymeric waveguide Bragg filters, the gratings pattern was first fabricated on an OG146 polymer (n^{Te}=1.5201 at 1.55 μm) with a length, width, and thickness of 4 cm , 1 cm, and 400 μm, respectively, by the above-mentioned process. The Bragg gratings (period: 0.5 μm; depth: 405 nm) placed on the center of the device were 0.8 mm long and 5 mm wide. A SU8 film was then spun coated on the gratings pattern of OG146 polymer at a spin rate of 5000 or 4000 rpm resulting in two different thick guiding layer (1.60 μm and 2.02 μm), and then cured at 90° C. for 5 min to form a planar waveguide (Referring to FIG. 2(j)). The thickness of the guiding layers was measured by using a prism coupler system (Metricon Inc., USA). After the end facet was polished, a polymeric optical filter (i.e. polymeric waveguide Bragg filter) was formed.

### V. Application of the Present Invention for the Fabrication of the Channel Waveguide Bragg Filter

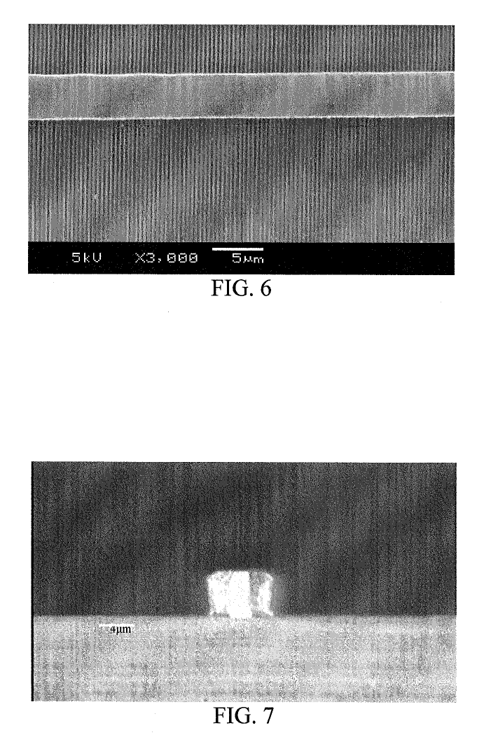

In addition, a channel waveguide Bragg grating filter is fabricated in the present invention. A Bragg gratings pattern of the same period and depth was fabricated on the OG146 polymer using the above-mentioned process. The Bragg grating was 3-mm long and 5-mm wide. Then, a SU-8 film was spun coated on the gratings pattern of the OG146 polymer at a spin rate of 1500 rpm. Finally, the channel waveguide gratings pattern with a width, thickness, and length of 4.7 μm, 3.3 μm, and 4 cm, respectively, was transferred onto the SU-8 film, and a channel waveguide Bragg grating filter was formed. FIG. 6 shows the top-view of SEM micrograph of the filter device and FIG. 7 shows the cross section of the channel waveguide.

For planar waveguide devices of the present invention (i.e. polymeric waveguide Bragg filter), the relative mode field of the polymer optical filters for a TE polarized light source at a wavelength of 1.55 μm was simulated using the beam propagation method (BPM-CAD, Opti-Wave Inc.). The effective index of the mode is 1.53968 for 1.6 μm-thick guiding layer sample and 1.547279 for 2.02 μm-thick guiding layer sample. Using the simulation, the transmission of the optical filter can be calculated by using the coupled mode theory [14, 15]. The Bragg wavelength λ_{B} is given as 2n_{eff}Λ, where n_{eff} is the mode effective index of the waveguide grating and Λ is the period of the grating. The calculated Bragg wavelength was 1539.68 nm for 1.6 μm-thick guiding layer sample and 1547.28 nm for 2.02 μm-thick guiding layer sample.

For the channel waveguide device of the present invention (i.e. channel waveguide Bragg grating filter), the effective index of the calculated effective index is 1.55043, and the calculated Bragg wavelength is 1550.43 nm.

### VI. The Waveguide Properties of the Present Invention

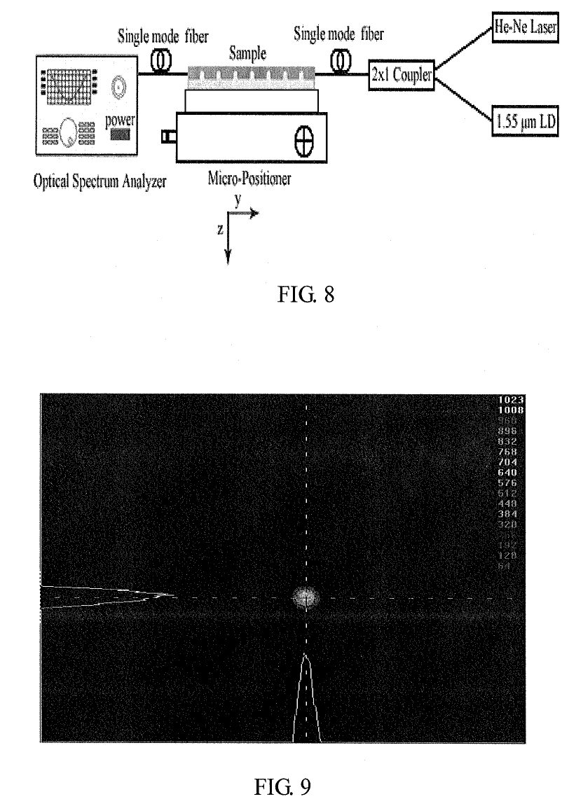

The near field patterns of the optical waveguide of the present invention were observed using the end-fire coupling technique. An amplified spontaneous emission (ASE) source with a wavelength range from 1525 to 1565 nm was used as the wide band light source (Stabilized Light Source, PTS-BBS, Newport Inc., USA). The light source was polarized in the TE direction using the in-line polarizer (ILP-55-N, Advanced Fiber Resources, China), which was followed by a polarization controller with operation wavelength around 1550 nm (F-POL-PC, Newport Inc., USA). The output mode field of the waveguide was observed using an IR CCD system (Model 7290A, Micron Viewer, Electrophysics Inc., U.S.A.) with image analysis software (LBA-710PC-D, V4.17, Spiricon Inc., USA). The measured mode field pattern of the waveguide shows the single-mode characteristics of the waveguide. FIG. 8 shows the mode field pattern of the channel waveguide device.

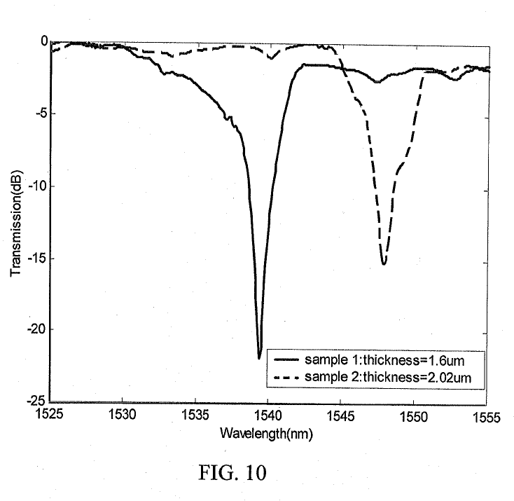

The spectral characteristics of the optical filter were measured using an optical spectrum analyzer. FIG. 9 shows the experimental setup of the transmission measurement system. ASE with wavelength range from 1520 to 1565 nm was used as the wide band light source. The ASE was polarized in TE direction using the in-line fiber polarizer (NXTAR Technology Inc., Taiwan, center wavelength: 1550 nm). A He—Ne laser source as the auxiliary source was combined to the wide band source using a 2×1 optical fiber coupler. The optical filter was set on a micro-positioner using a waveguide holder, and two single mode fibers were used as the input and output fibers. Then the output fiber was connected to the optical spectrum analyzer to characterize the filtering performance. The measured results of the planar waveguide devices are shown in FIG. 10. In this experiment, the minimum resonant wavelength was confirmed as the Bragg wavelength. These results are similar to the theoretical predicted ones. The Bragg wavelength of the 1.6 μm-thick guiding layer sample is measured at 1539 nm, and the 2.02 μm-thick guiding layer sample is measured at 1547 nm. The Bragg wavelength increased as the output fiber deviated and the deviation of the resonant wavelength is approximately 1 nm. Similarly, the Bragg wavelength of the channel waveguide filter is about 1549 nm.

For planar waveguide devices at the Bragg wavelength for the 1.6 μm-thick guiding layer sample, a transmission dip of −23 dB was obtained, and the 3-dB-transmission bandwidth was approximately 5.8 nm. For the 2.02 μm-thick guiding layer sample, a transmission dip of −16 dB was obtained, and the 3-dB-transmission bandwidth was approximately 4.5 nm. When the thickness of the guiding layer is decreased, it will result in a deep transmission dip, thereby broadening the bandwidth. This may occur because when the thickness of the guiding layer is decreased, the mode field is broadened and then the propagation light can deeply penetrate the substrate. Therefore, the coupling coefficient between forward and backward propagation modes was increased, resulting in broadening the bandwidth and the deep transmission dip. In comparison with previous results, the transmission bandwidth is much wider in this invention due to the thinner waveguide thickness and larger grating depth, resulting in a larger coupling coefficient for our devices. The effective index of the waveguide grating was 1.53968 for 1.6 μm-thick sample and 1.547279 for 2.02 μm-thick sample, which are consistent with the experiment results.

For the channel waveguide device, the transmission spectrum is similar to the planar waveguide devices. At the Bragg wavelength, a transmission dip of approximately −13dB was obtained and the bandwidth is approximately 4 nm.

### VII. Conclusion

In conclusion, we have successfully created a process to fabricate polymeric wavelength filters by using both micro-molding and holographic interference techniques. A good aspect ratio on the gratings pattern could be obtained. The grating period was 500 nm and the depth was 300 nm with 0.8-mm-long, and the grating is in the bottom of the guiding layer. Two different thick guiding layers were used. For the 1.6 μm thick guiding layer sample, a transmission dip of −23 dB was obtained, and the 3-dB-transmission bandwidth was about 5.8 nm. For the 2.02 μm thick guiding layer sample, a transmission dip of −16 dB was obtained, and the 3-dB-transmission bandwidth was about 4.5 nm.

While the invention has been described in terms of what are presently considered to be the most practical and preferred embodiments, it is to be understood that the invention need not to be limited to the disclosed embodiment. On the contrary, it is intended to cover various modifications and similar arrangements included within the spirit and scope of the appended claims, which are to be accorded with the broadest interpretation so as to encompass all such modifications and similar structures.

What is claimed is:

1. A method for fabricating the polymer wavelength filter, which comprises following steps:
(A) a positive photo-resister film coated on a first substrate;
(B) a gratings pattern holographically exposed using a two-beam interference pattern on the positive photo-resister film;
(C) a nickel thin film was then sputtered onto the positive photo-resister film;
(D) at least a spacer placed between the nickel film and a thin glass slide, a tunnel formed between the nickel film and the glass slide;
(E) forming a UV polymer substrate in the tunnel by an injected molding process;
(F) removing the photo-resister film and the first substrate;
(G) removing the nickel film; and
(H) a polymer film spun coated on the UV polymer substrate, and cured to obtain a polymer wavelength filter.

2. The method as claimed in claim 1, wherein step (C), the nickel film with the thickness of approximately 20 nm was sputtered onto the positive photo-resister by an RF sputtering system for about 1 min, and a work pressure is restricted to less than 5×10⁻³ Torr.

3. The method as claimed in claim 1, wherein step (D), the thickness of the spacer is 400 μm, and the glass slide is Pyrex glass.

4. The method as claimed in claim 1, wherein step (E), the UV polymer is OG 146 polymer.

5. The method as claimed in claim 1, wherein step (E), injecting the procure UV polymers into the tunnel between the nickel mold and the glass slide by using a fine tip syringe, the liquid solution of the procure UV polymers automatically spread and filled up the tunnel, a UV curing lamp with a wavelength range of 300-400 nm was used to crosslink the UV polymer at an intensity of 100 mW/cm² for 1 to 2 min.

6. The method as claimed in claim 1, wherein step (F), the positive photo-resister film is removed by an acetone solution.

7. The method as claimed in claim 1, wherein step (G), the nickel film is etched away from the UV polymer substrate by the FeCl₃ etching solution.

8. The method as claimed in claim 7, wherein the ratio of the solution FeCl₃: H₂O=1:1, and the temperature is maintained at 25° C.

9. The method as claimed in claim 1, wherein step (H), the polymer coated on the UV polymer substrate is SU8 polymer (Micro Chem SU8-2005) as a core layer having a optical loss <0.4 dB/cm and a refractive index between 1.56 and 1.57 at a wavelength of 1.55 μm.

10. The method as claimed in claim 1, wherein step (H), the polymer is SU8 polymer spun coated on the UV polymer substrate at a spin rate of 5000 or 4000 rpm resulting in two different thickness of 1.60 μm or 2.02 μm, and then cured at 90° C. for 5 min.

11. The method as claimed in claim 1, wherein step (H), the polymer is SU8 polymer spun coated on the UV polymer substrate at a spin rate of 1500 rpm.

12. A method for fabricating the polymeric waveguide filter, which comprises following steps:
(A) a positive photo-resister film coated on a first substrate;
(B) a gratings pattern holographically exposed using a two-beam interference pattern on the positive photo-resister film;
(C) a nickel thin film was then sputtered onto the positive photo-resister film;
(D) at least a spacer placed between the nickel film and a thin glass slide, a tunnel formed between the nickel film and the glass slide;
(E) forming a OG 146 polymer substrate in the tunnel by an injected molding process;
(F) removing the photo-resister film and the first substrate;
(G) removing the nickel film; and
(H) a SU8 polymer spun coated on the OG 146 polymer substrate at a spin rate of 5000 or 4000 rpm resulting in the thickness of 1.60 μm or 2.02 μm, then cured to obtain a polymeric waveguide Bragg filter.

13. The method as claimed in claim 12, wherein step (E), injecting the procure OG 146 polymer into the tunnel by using a fine tip syringe, the liquid solution of the procure OG 146 polymer automatically spread and filled up the tunnel, a UV curing lamp with a wavelength range of 300-400 nm was used to crosslink the OG 146 polymer at an intensity of 100 mW/cm² for 1-2 min.

14. The method as claimed in claim 12, wherein step (F), the positive photo-resister film is removed by an acetone solution.

15. The method as claimed in claim 12, wherein step (G), the nickel film is etched away from the OG 146 polymer substrate by the FeCl₃ etching solution.

16. The method as claimed in claim 15, wherein the ratio of the solution FeCl₃: H2O=1:1, and the temperature is maintained at 25° C.

17. A method for fabricating the polymeric waveguide filter, which comprises following steps:
(A) a positive photo-resister film coated on a first substrate;
(B) a gratings pattern holographically exposed using a two-beam interference pattern on the positive photo-resister film;
(C) a nickel thin film was then sputtered onto the positive photo-resister film;
(D) at least a spacer placed between the nickel film and a thin glass slide, a tunnel formed between the nickel film and the glass slide;
(E) forming a OG 146 polymer substrate in the tunnel by an injected molding process;
(F) removing the photo-resister film and the first substrate;
(G) removing the nickel film; and
(H) a SU8 polymer spun coated on the OG 146 polymer substrate at a spin rate of 1500 rpm, and then cured to obtain a channel waveguide Bragg grating filter.

18. The method as claimed in claim 13, wherein step (E), injecting the procure OG 146 polymer into the tunnel by using a fine tip syringe, the liquid solution of the procure OG 146 polymer automatically spread and filled up the tunnel, a UV curing lamp with a wavelength range of 300-400 nm was used to crosslink the OG 146 polymer at an intensity of 100 mW/cm² for 1-2 min.

19. The method as claimed in claim 12, wherein step (F), the positive photo-resister film is removed by an acetone solution.

20. The method as claimed in claim 12, wherein step (G), the nickel film is etched away from the OG 146 polymer substrate by the FeCl₃ etching solution, the ratio of the solution FeCl₃: H₂O=1:1, and the temperature is maintained at 25° C.
